(19) United States
(12) Patent Application Publication
(10) Pub. No.: US 2026/0247764 A1
(43) Pub. Date: Aug. 20, 2026

(54) LIGHT EMITTING DEVICE AND IMAGE DISPLAY DEVICE

(71) Applicants: SONY SEMICONDUCTOR SOLUTIONS CORPORATION, Kanagawa (JP); SONY GROUP CORPORATION, Tokyo (JP)

(72) Inventors: Toru SASAKI, Kanagawa (JP); Kei KIMURA, Kanagawa (JP); Toshihiko WATANABE, Tokyo (JP)

(73) Assignees: SONY SEMICONDUCTOR SOLUTIONS CORPORATION, Kanagawa (JP); SONY GROUP CORPORATION, Tokyo (JP)

(21) Appl. No.: 19/156,019

(22) PCT Filed: Feb. 2, 2024
(86) PCT No.: PCT/JP2024/003556

§ 371 Date: Aug. 13, 2025

(30) Foreign Application Priority Data
Feb. 20, 2023 (JP) 2023-024685

(51) Int. Cl. H10H 20/855; H10H 20/01; H10H 20/821; H10H 20/851; H10H 29/49

(52) U.S. Cl. CPC H10H 20/855; H10H 20/0361; H10H 20/0363; H10H 20/821; H10H 20/851; H10H 29/49

(57) ABSTRACT

A light emitting device according to an embodiment of the present disclosure includes: a driving circuit substrate; and an element substrate that has a first surface and a second surface, the first surface serving as a light exit surface, the second surface being on a side opposite to the first surface and being opposed to the driving circuit substrate, that includes a pixel array section including a plurality of pixels disposed in an array form, and that includes two or more light emitting elements having mesa structures for each of the pixels.

### TECHNICAL FIELD

The present disclosure relates to a light emitting device and an image display device provided with the same.

### BACKGROUND ART

For example, Patent Literature 1 discloses a micro-LED formed by covering a crystal growth substrate with a mask layer having a plurality of openings and by selectively growing one or a plurality of semiconductor rods having a first semiconductor layer of a first conductivity type and a second semiconductor layer of a second conductivity type through metalorganic chemical vapor deposition (MOCVD).

### CITATION LIST

### Patent Literature

Patent Literature 1: International Publication No. WO 2020/136848

### SUMMARY OF THE INVENTION

Meanwhile, it has been desired for light emitting devices to achieve both refinement and improvement in luminance.

It is desirable to provide a light emitting device and an image display device that make it possible to achieve both refinement and improvement in luminance.

A light emitting device according to an embodiment of the present disclosure includes: a driving circuit substrate; and an element substrate that has a first surface and a second surface, the first surface serving as a light exit surface, the second surface being on a side opposite to the first surface and being opposed to the driving circuit substrate, that includes a pixel array section including a plurality of pixels disposed in an array form, and that includes two or more light emitting elements having mesa structures for each of the pixels.

An image display device according to an embodiment of the present disclosure includes a light emitting device. As the light emitting device, the image display device includes the above-described light emitting device according to the embodiment of the present disclosure.

A light emitting device and an image display device according to an embodiment of the present disclosure are provided with two or more light emitting elements for each pixel, the light emitting element having a mesa structure. This makes it possible to add redundancy to each pixel.

### BRIEF DESCRIPTION OF THE DRAWINGS

FIG. 1 is a schematic cross-sectional view illustrating an example of a configuration of a light emitting device according to an embodiment of the present disclosure.

FIG. 2 is a schematic diagram illustrating an example of a planar configuration of the whole light emitting device illustrated in FIG. 1.

FIG. 3 is a schematic diagram enlarging a portion of the planar configuration of the light emitting device illustrated in FIG. 2.

FIG. 4 is a schematic plan view illustrating an example of layout of light emitting elements in each of pixels of the light emitting device illustrated in FIG. 1.

FIG. 5 is a diagram for describing an example of a method of controlling luminance of each of the pixels of the light emitting device illustrated in FIG. 1.

FIG. 6 is a diagram for describing another example of the method of controlling luminance of each of the pixels of the light emitting device illustrated in FIG. 1.

FIG. 7A is a schematic cross-sectional view for describing an example of a manufacturing process of the light emitting device illustrated in FIG. 1.

FIG. 7B is a schematic cross-sectional view illustrating a subsequent process after FIG. 7A.

FIG. 7C is a schematic cross-sectional view illustrating a subsequent process after FIG. 7B.

FIG. 7D is a schematic cross-sectional view illustrating a subsequent process after FIG. 7C.

FIG. 7E is a schematic cross-sectional view illustrating a subsequent process after FIG. 7D.

FIG. 7F is a schematic cross-sectional view illustrating a subsequent process after FIG. 7E.

FIG. 7G is a schematic cross-sectional view illustrating a subsequent process after FIG. 7F.

FIG. 7H is a schematic cross-sectional view illustrating a subsequent process after FIG. 7G.

FIG. 7I is a schematic cross-sectional view illustrating a subsequent process after FIG. 7H.

FIG. 8A is a schematic cross-sectional view illustrating a subsequent process after FIG. 7F.

FIG. 8B is a schematic cross-sectional view illustrating a subsequent process after FIG. 8A.

FIG. 8C is a schematic cross-sectional view illustrating a subsequent process after FIG. 8B.

FIG. 8D is a schematic cross-sectional view illustrating a subsequent process after FIG. 8C.

FIG. 8E is a schematic cross-sectional view illustrating a subsequent process after FIG. 8D.

FIG. 8F is a schematic cross-sectional view illustrating a subsequent process after FIG. 8E.

FIG. 8G is a schematic cross-sectional view illustrating a subsequent process after FIG. 8F.

FIG. 8H is a schematic cross-sectional view illustrating a subsequent process after FIG. 8G.

FIG. 8I is a schematic cross-sectional view illustrating a subsequent process after FIG. 8H.

FIG. 8J is a schematic cross-sectional view illustrating a subsequent process after FIG. 8I.

FIG. 8K is a schematic cross-sectional view illustrating a subsequent process after FIG. 8J.

FIG. 8L is a schematic cross-sectional view illustrating a subsequent process after FIG. 8K.

FIG. 8M is a schematic cross-sectional view illustrating a subsequent process after FIG. 8L.

FIG. 8N is a schematic cross-sectional view illustrating a subsequent process after FIG. 8M.

FIG. 9 is a diagram for describing pre-correction luminances (A) and post-correction luminances (B) of respective pixels of a general light emitting device according to a comparative example.

FIG. 10 is a diagram for describing a relation between luminance of respective pixels and luminance of respective light emitting elements of the general light emitting device. FIG. 11 is a diagram for describing a relation between luminance of respective pixels and luminance of respective light emitting elements of the light emitting device illustrated in FIG. 1.

FIG. 12 is a diagram for describing pre-correction luminances (A) and post-correction luminances (B) of the respective light emitting elements in each of the pixels of the light emitting device illustrated in FIG. 1.

FIG. 13 is a schematic diagram illustrating an example of a planar configuration of a whole light emitting device according to a modification of the present disclosure.

FIG. 14 is a schematic diagram enlarging a portion of the planar configuration of the light emitting device illustrated in FIG. 13.

FIG. 15 is a perspective view illustrating an example of a configuration of an image display device according to an application example of the present disclosure.

FIG. 16 is a schematic diagram illustrating an example of a wiring layout of the image display device illustrated in FIG. 15.

FIG. 17 is a perspective view illustrating an example of a configuration of an image display device according to an application example of the present disclosure.

FIG. 18 is a perspective view illustrating a configuration of a mounting substrate illustrated in FIG. 17.

FIG. 19 is a perspective view illustrating a configuration of a unit substrate illustrated in FIG. 18.

FIG. 20 is a diagram illustrating an example of the image display device according to the application examples of the present disclosure.

### MODES FOR CARRYING OUT THE INVENTION

Next, with reference to drawings, details of an embodiment of the present disclosure will be described. The following description is a specific example of the present disclosure, and the present disclosure is not limited to the following embodiments. In addition, the present disclosure is not limited to placements, dimensions, dimensional ratios, and the like of respective structural elements in each diagram. It is to be noted that the description will be given in the following order.
1. First Embodiment (example of light emitting device including a plurality of light emitting elements disposed in each pixel)
1-1. Configuration of Light Emitting Device
1-2. Manufacturing Method of Light Emitting Device
1-3. Actions and Effects
2. Modification (another example of light emitting device)
3. Application Examples

### 1. Embodiment

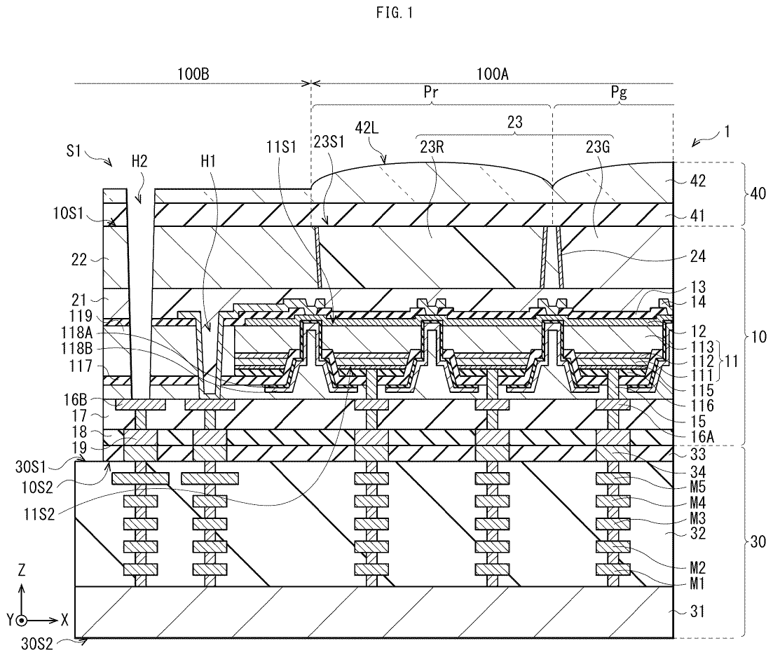

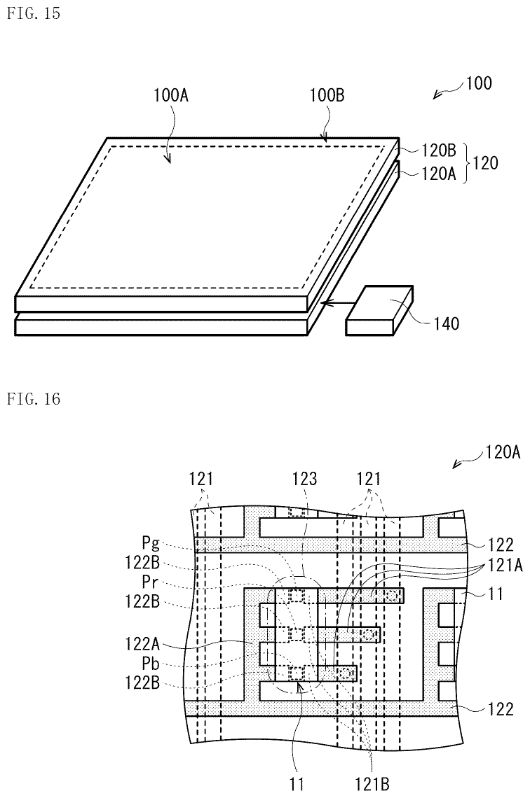

FIG. 1 schematically illustrates an example of a cross-sectional configuration of a light emitting device (light emitting device 1) according to an embodiment of the present disclosure. FIG. 2 schematically illustrates an example of a planar configuration of the whole light emitting device 1 illustrated in FIG. 1. The light emitting device 1 is suitably applicable to an image display device (for example, image display device 100, see FIG. 15) which is a so-called LED display.

### 1-1. Configuration of Light Emitting Device

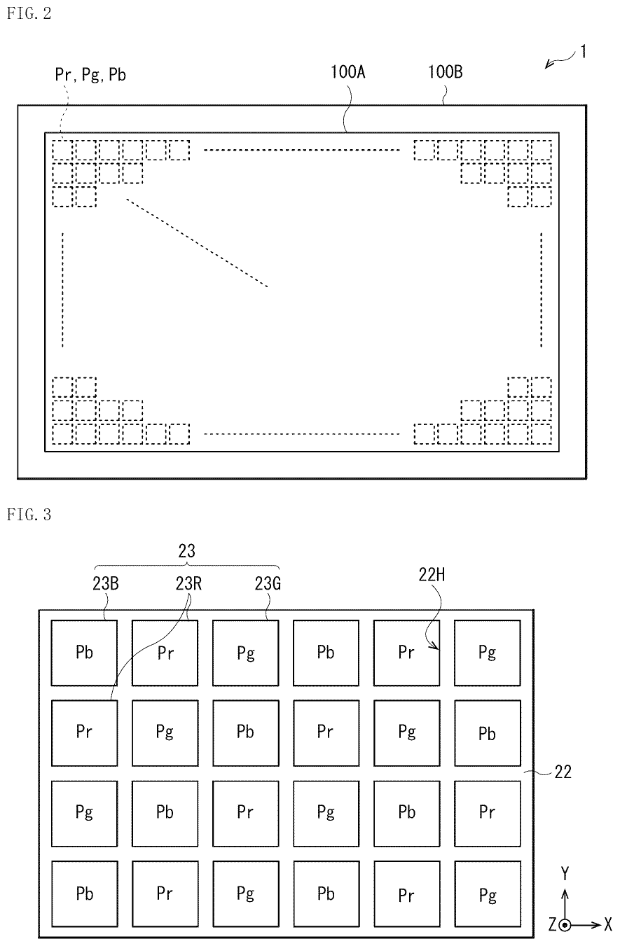

The light emitting device 1 is obtained by joining an element substrate 10 and a driving circuit substrate 30 through hybrid bonding. For example, as illustrated in FIG. 3, the light emitting device 1 includes a display region 100A and a frame region 100B, the display region 100A including, for example, a plurality of rectangular pixels (for example, red pixels Pr, green pixels Pg, and blue pixels Pb) that are two-dimensionally arrayed, the frame region 100B being disposed around the display region 100A. The element substrate 10 has a surface 10S1 and a surface 10S2. The surface 10S1 serves as a light exit surface. The surface 10S2 is on a side opposite to the surface 10S1. The driving circuit substrate 30 is stacked on the surface-10S2 side of the element substrate 10. The driving circuit substrate 30 has a surface 30S1 and a surface 30S2. The surface 30S1 is opposed to the element substrate 10. The surface 30S2 is on a side opposite to the surface 30S1. The driving circuit substrate 30 is provided with a driving circuit or the like for controlling driving of the plurality of light emitting elements 11 disposed in the display region 100A. In the present embodiment, the two or more (for example, four) light emitting elements 11 having a mesa structure are disposed for each of color pixels Pr, Pg, and Pb.

In the present embodiment, the element substrate 10 corresponds to a specific example of an “element substrate” according to an embodiment of the present disclosure. The surface 10S1 corresponds to a “first surface” according to an embodiment of the present disclosure. The surface 10S2 corresponds to a “second surface” according to an embodiment of the present disclosure. In addition, the display region 100A corresponds to a specific example of a “pixel array section” according to an embodiment of the present disclosure. The display the red pixels Pr, green pixels Pg, and blue pixels Pb correspond to a specific example of a “plurality of pixels” according to an embodiment of the present disclosure. The driving circuit substrate 30 corresponds to a specific example of a “driving circuit substrate” according to an embodiment of the present disclosure.

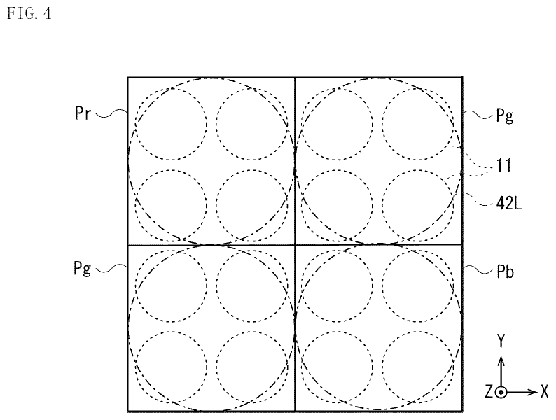

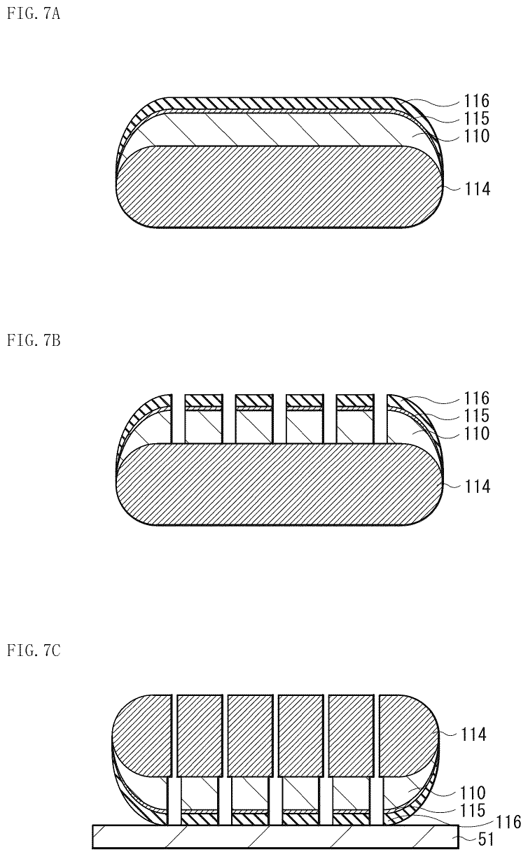

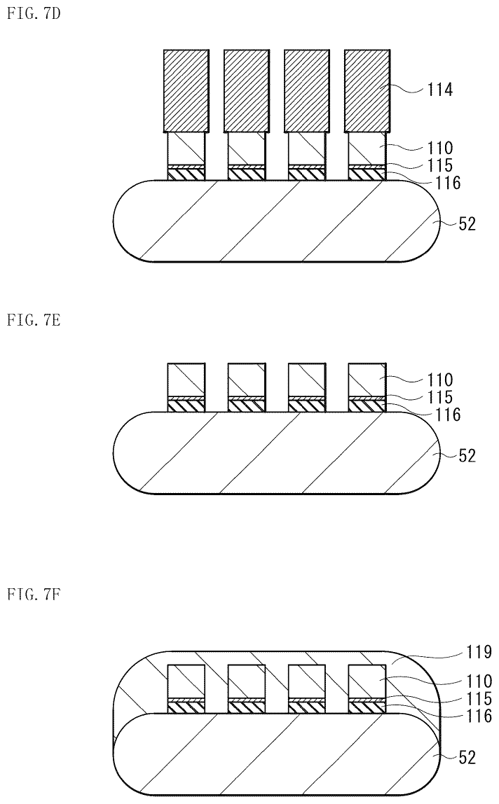

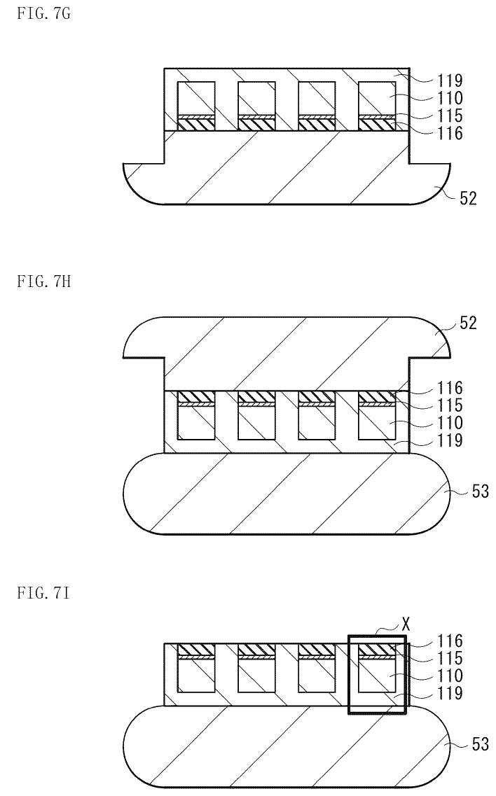

The element substrate 10 includes the plurality of light emitting elements 11 that are obtained by separating a compound semiconductor layer 110 (see FIG. 7) extending in the display region 100A. For example, as illustrated in FIG. 4, the plurality of light emitting elements 11 has substantially circular planar shapes and is disposed in an array form in a row direction (for example, X-axis direction) and in a column direction (for example Y-axis direction), for example. Among the plurality of light emitting elements 11 disposed in the array form in the row direction and the column direction, for example, four light emitting elements disposed in two rows and two columns are disposed in each of the color pixels Pr, Pg, and Pb. On a light-extraction-surface (surface 11S1) side of the plurality of the light emitting elements 11, an electrode layer 12 successive to the plurality of light emitting elements 11 is formed. On a surface 11S2 side of the plurality of the light emitting elements 11, electrode layers 115, insulating layers 116, protection layers 117, an insulating film 118A, and a reflection film 118B are formed. The electrode layer 115, the insulating layer 116, and the protection layer 117 are provided for each element. The insulating film 118A and the reflection film 118B are successive to the plurality of light emitting elements 11. The element substrate 10 further includes an embedding layer 119, an insulating layer 17, and an insulating layer 18 on the driving-circuit-substrate 30 side. The embedding layer 119 embeds the plurality of light emitting elements 11 from the surface 10S2 side. The embedding layer 119 includes plugs 15 provided for the respective elements. The insulating layer 17 includes pad sections 16A provided for the respective elements in the display region 100A and pad electrodes 16B provided in the frame region 100B. The insulating layer 18 forms a joint surface to be joined to the driving circuit substrate 30, and includes a plurality of pad sections 19 that bonds the element substrate 10 and the driving circuit substrate 30 electrically and physically.

The light emitting element 11 corresponds to a specific example of a “light emitting element” according to an embodiment of the present disclosure. The light emitting element 11 is a solid-state light emitting element that emits light of a predetermined wavelength band from the surface 11S1, such as a light emitting diode (LED) chip. The LED chip represents a chip obtained by cutting a wafer whose crystal has grown, which is not in a package type surrounded by a molding resin or the like. The LED chip is called a micro LED since it has a size of, for example, 5 μm or above and 100 μm or less.

The light emitting element 11 includes a first conductivity-type layer 111, an active layer 112, and a second conductivity-type layer 113 that are stacked in this order, and the second conductivity-type layer 113 has an upper surface serving as a light exit surface (surface 11S1).

For example, the first conductivity-type layer 111 is formed by an n-type GaN-based semiconductor material. The active layer 112 has, for example, a multi-quantum-well structure in which InGaN and GaN are alternately stacked, and has a light emitting region therein. From the active layer 112, for example, light in a blue band of 430 nm or more and 500 nm or less is extracted. In addition, light having a wavelength corresponding to, for example, an ultraviolet region (ultraviolet light) may be extracted from the active layer 112. For example, the second conductivity-type layer 113 is formed by a p-type GaN-based semiconductor material.

The electrode layer 12 serves as a common electrode for the plurality of light emitting elements 11 and is successively formed on the respective surfaces 11S1 of the plurality of light emitting elements 11. The electrode layer 12 is in ohmic contact with the second conductivity-type layer 113. For example, the electrode layer 12 is formed by transparent electrode material such as zinc oxide (ZnO), ITO, indium zinc oxide (IZO), tin oxide (SnO), or TiO. For example, in the frame region 100B, the electrode layer 12 is electrically coupled to the pad electrode 16B via an opening H1 that penetrates the protection layer 117 and the embedding layer 119 and that has a bottom to which the pad electrode 16B is exposed.

The electrode layer 115 is formed on a lower surface (surface 11S2) of the first conductivity-type layer 111 of the light emitting element 11. The electrode layer 115 is in ohmic contact with the first conductivity-type layer 111. For example, the electrode layer 115 is formed by transparent conductive material such as a multilayer film (Ni/Au) of nickel (Ni) and gold (Au), ITO, or the like.

The insulating layer 116 is provided on the electrode layer 115. The insulating layer 116 is formed by silicon oxide (SiO), silicon nitride (SiN), or the like, for example.

On the driving-circuit-substrate 30 side, the light emitting element 11 has the mesa structure including the first conductivity-type layer 111, the active layer 112, and a portion of the second conductivity-type layer 113. The surface 11S2 of the light emitting element 11, and side surfaces of the first conductivity-type layer 111, the active layer 112, and the portion of the second conductivity-type layer 113 that are processed into the mesa shape are covered with the protection layer 117. The protection layer 117 is formed by silicon oxide (SiO), silicon nitride (SiN), or the like, for example.

In addition, a surface of the protection layer 117 and a side surface of the second conductivity-type layer 113 exposed from the protection layer 117 are covered with a stacked film including the insulating film 118A and the reflection film 118B. The stacked film is successively formed for the plurality of light emitting elements 11. The stacked film has an opening 118H on the surface 11S2 side of the light emitting element 11, and a plug 15 is formed in the opening 118H.

The plugs 15 apply voltages to the respective first conductivity-type layers 111 of the plurality of light emitting elements 11. The plugs 15 are formed by using copper (Cu), aluminium (Al), tungsten (W), silver (Ag), or alloys thereof, for example.

The embedding layer 119 embeds the plurality of light emitting elements 11 and forms a flat stacked surface over the display region 100A and the frame region 100B on the driving-circuit-substrate 30 side. In the frame region 100B, the embedding layer 119 also forms a flat surface successive to the surfaces 11S1 of the plurality of light emitting elements 11. The embedding layer 119 is formed by silicon oxide (SiO), silicon nitride (SiN), or the like, for example.

The driving-circuit-substrate 30 side of the embedding layer 119 is provided with the insulating layer 17. In the insulating layer 17, the plurality of pad sections 16A is formed for the respective light emitting elements 11A in the display region 100A, and the pad electrodes 16B and vias are formed in the frame region 100B. The insulating layer 17 is formed by silicon oxide (SiO), silicon nitride (SiN), or the like, for example. The pad sections 16A, the pad electrodes 16B, and the vias are formed by using copper (Cu), aluminium (Al), tungsten (W), silver (Ag), or alloys thereof, for example.

In addition, the driving-circuit-substrate 30 side of the insulating layer 17 is provided with the insulating layer 18 that forms the joint surface to be joined to the driving circuit substrate 30. As described above, the insulating layer 18 forms the joint surface to be joined to the driving circuit substrate 30, and includes the plurality of pad sections 19 that bonds the element substrate 10 and the driving circuit substrate 30 electrically and physically. The insulating layer 18 is formed by silicon oxide (SiO), silicon nitride (SiN), or the like, for example. The pad sections 19 are formed by using copper (Cu), for example.

The element substrate 10 further includes a planarizing layer 21, a partition wall layer 22, and a wavelength conversion layer 23 on the surface 10S1 side. For example, the partition wall layer 22 has openings 22H for the respective color pixels Pr, Pg, and Pg, and the wavelength conversion layer 23 is formed inside the openings 22H. In addition, a reflection film 24 is provided between the partition wall layer 22 and the wavelength conversion layer 23.

The planarizing layer 21 planarizes the light extraction surface (surface 11S1) of the display region 100A including the plurality of light emitting elements 11 disposed in the array form. The planarizing layer 21 is formed by silicon oxide (SiO), silicon nitride (SiN), or the like, for example.

The partition wall layer 22 suppresses occurrence of color mixing due to leakage of light into different color pixels that are adjacent to each other when applying the light emitting device 100 to the image display device 100. As illustrated in FIG. 3, the partition wall layer 22 has, for example, the generally rectangular openings 22H for the respective color pixels Pr, Pg, and Pb disposed in the array form. For example, in cross-sectional view, the openings 22H have inclined surfaces of less than 90° with respect to a surface of the partition wall layer 22 that is opposed to the light emitting elements 11. That is, the partition wall layer 22 has side surfaces having forward tapered shapes between the adjacent color pixels Pr, Pg, and Pb in cross-sectional view. The partition wall layer 22 is preferably formed by using material having a high thermal conductivity and a high electric conductivity. For example, the partition wall layer 22 is formed by using metal material such as copper (Cu), aluminium (Al), gold (Au), nickel (Ni), or platinum (Pt).

The wavelength conversion layer 23 converts light emitted from the plurality of light emitting elements 11 disposed in the respective color pixels Pr, Pg, and Pb into desired wavelengths (for example, red (R)/green (G)/blue (B)) and outputs the converted light. The wavelength conversion layer 23 is formed in the openings 22H made for the respective color pixels Pr, Pg, and Pb. Specifically, the red pixel Pr is provided with a red wavelength conversion layer 23R that converts light emitted from four light emitting elements 11 into red band light (red light), the green pixel Pg is provided with a green wavelength conversion layer 23G that converts light emitted from four light emitting elements 11 into green band light (green light), and the blue pixel Pb is provided with a blue wavelength conversion layer 23B that converts light emitted from four light emitting elements 11 into blue band light (blue light).

It is possible to form the wavelength conversion layers 23R, 23G, and 23B by using quantum dots corresponding to the respective colors. Specifically, in a case of obtaining the red light, it is possible to select the quantum dots from among InP, GaInP, InAsP, CdSe, CdZnSe, CdTeSe, CdTe, and the like, for example. In a case of obtaining the green light, it is possible to select the quantum dots from among InP, GaInP, ZnSeTe, ZnTe, CdSe, CdZnSe, CdS, CdSeS, and the like, for example. In a case of obtaining the blue light, it is possible to select the quantum dots from among ZnSe, ZnTe, ZnSeTe, CdSe, CdZnSe, CdS, CdZnS, CdSeS, and the like. It is to be noted that, in a case where a light emitting element 11 emits the blue light as described above, the blue wavelength conversion layer 23B may be formed by a transparent resin layer having light transparency.

The reflection film 24 is provided on side surfaces of the openings 22H for efficiency extracting, from a light extraction surface (surface 23S1) of the wavelength conversion layer 23, the respective color light beams that are emitted from the plurality of light emitting elements 11 and converted by the respective wavelength conversion layers 23R, 23G, and 23B. The reflection film 24 is formed by using metal material having light reflectivity. Examples of the metal material used for forming the reflection film 24 include metals having high reflectance in a visible light region. Specific examples of the material include silver (Ag), aluminium (Al), copper (Cu), gold (Au), platinum (Pt), rhodium (Rh), alloys thereof, and the like.

It is to be noted that the reflection film 24 does not necessarily have to be formed in a case where the partition wall layer 22 is formed by using the above-described metal material having the light reflectivity.

In addition, an optical structure section 40 may be formed on a light-exit-surface S1 side of the element substrate 10. The optical structure section 40 includes a protection layer 41 and an on-chip lens layer 42. The protection layer 41 is formed over the display region 100A and the frame region 100B. The on-chip lens layer 42 is provided on the protection layer 41.

The protection layer 41 for protecting a surface of the wavelength conversion layer 23 is formed by silicon oxide (SiO), silicon nitride (SiN), or the like, for example.

The on-chip lens layer 42 is provided to cover the whole display region 100A and the whole frame region 100B. The on-chip lens layer 42 includes a plurality of on-chip lenses 42L that have a predetermined curvature and that output incident light into a predetermined direction. As illustrated in FIG. 4, the on-chip lenses 42L are disposed for the respective color pixels Pr, Pg, and Pb. The on-chip lens layer 42 includes light transmissive material. For example, the on-chip lens layer 42 includes a monolayer film containing one selected from the group consisting of silicon oxide (SiO), silicon nitride (SiN), silicon oxynitride (SiCN), and the like, or alternatively, the on-chip lens layer 42 includes a stacked film containing at least two selected therefrom.

The driving circuit substrate 30 is provided with a plurality of constant current driving circuits that flow a fixed electric current to the plurality of light emitting elements 11 disposed in the display region 100A, for example. The driving circuit substrate 30 includes a support substrate 31, an interlayer insulating layer 32, an insulating layer 33, and pad sections 34. The interlayer insulating layer 32 is provided on the support substrate 31 and includes a plurality of wiring layers (for example, wiring layers M1, M2, M3, M4, and M5) and vias for electrically coupling the wiring layers. The insulating layer 33 forms a joint surface to be joined to the element substrate 10. The pad sections 34 are embedded in the insulating layer 33.

The plurality of constant current driving circuits includes respective control elements 35 that control electric currents flowing into the light emitting elements 11, and is electrically coupled to the plurality of light emitting elements 11 via the pad sections 19 provided on the joint surface (surface 10S2) of the element substrate 10 and the pad sections 34 provided on the joint surface (surface 30S1) of the driving circuit substrate 30, for example.

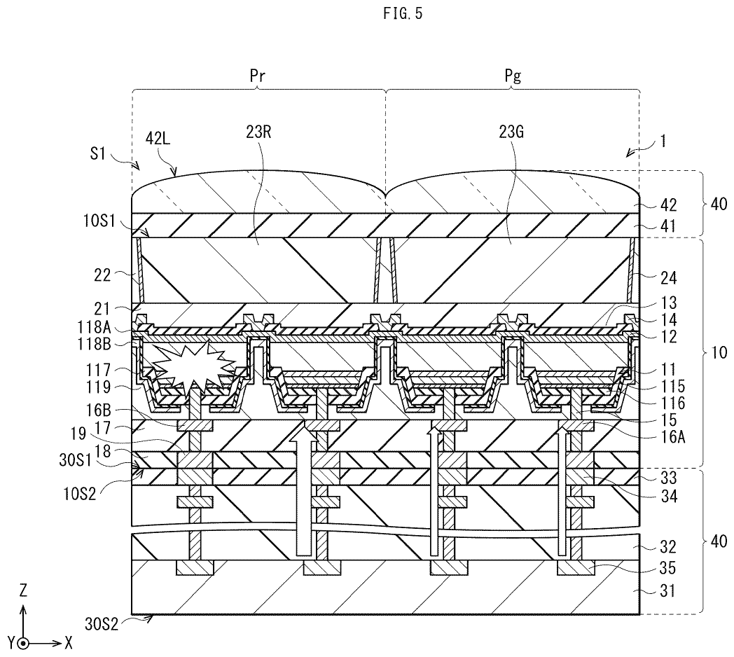

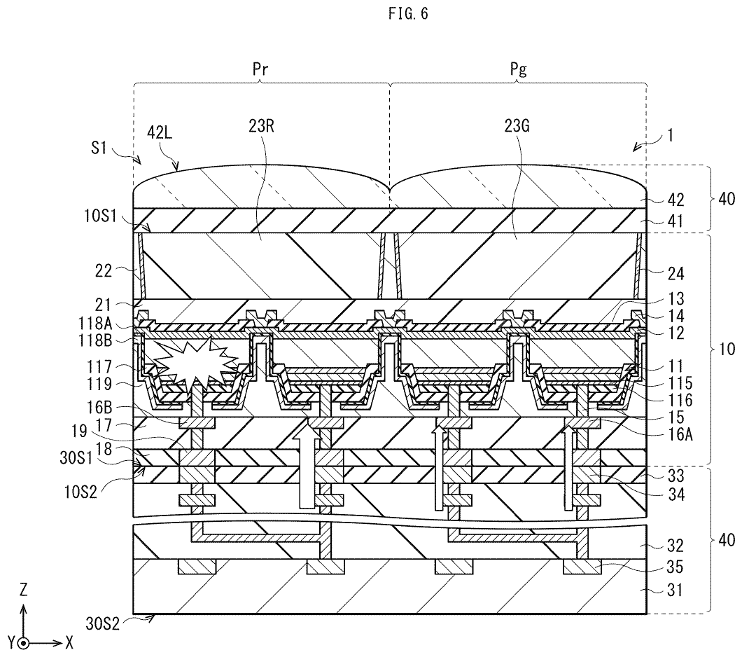

FIG. 5 and FIG. 6 are diagrams for describing examples of a method of controlling luminance of each of the pixels (for example, red pixel Pr and green pixel Pg) of the light emitting device 1 illustrated in FIG. 1. It is to be noted that arrows illustrated in FIG. 5 and FIG. 6 represent amounts of electric current flowing into the respective light emitting elements 11.

For example, the plurality of light emitting elements 11 provided for the respective color pixels Pr and Pg is coupled to the constant current driving circuits individually. Therefore, for example, even in a case where one of the plurality of light emitting elements 11 provided for the respective color pixels Pr and Pg causes a bright dot defect due to its failure as illustrated in FIG. 5, it is possible to maintain luminance per pixel by turning off operation of a control element 35 coupled to the faulty light emitting element 11 and controlling (here, increasing) amounts of electric current flowing into other light emitting elements 11.

For example, the plurality of light emitting elements 11 provided for the respective color pixels Pr and Pg is coupled to each other and is coupled to a single constant current driving circuits. Therefore, for example, even in a case where one of the plurality of light emitting elements 11 provided for the respective color pixels Pr and Pg causes the bright dot defect due to its failure as illustrated in FIG. 6, it is possible to maintain luminance per pixel since electric current does not flow into the faulty light emitting element 11 but large amounts of electric current flow into other light emitting elements 11 through trimming.

The interlayer insulating layer 32 is formed by silicon oxide (SiO), silicon nitride (SiN), or the like, for example.

The wiring layers M1, M2, M3, M4, and M5 and the vias for electrically coupling the respective wiring layers are formed by using copper (Cu), aluminium (Al), tungsten (W), silver (Ag), or alloys thereof, for example. The insulating layer 33 is formed by silicon oxide (SiO), silicon nitride (SiN), or the like, for example. The pad sections 34 are formed by using copper (Cu), for example.

### 1-2. Manufacturing Method of Light Emitting Device

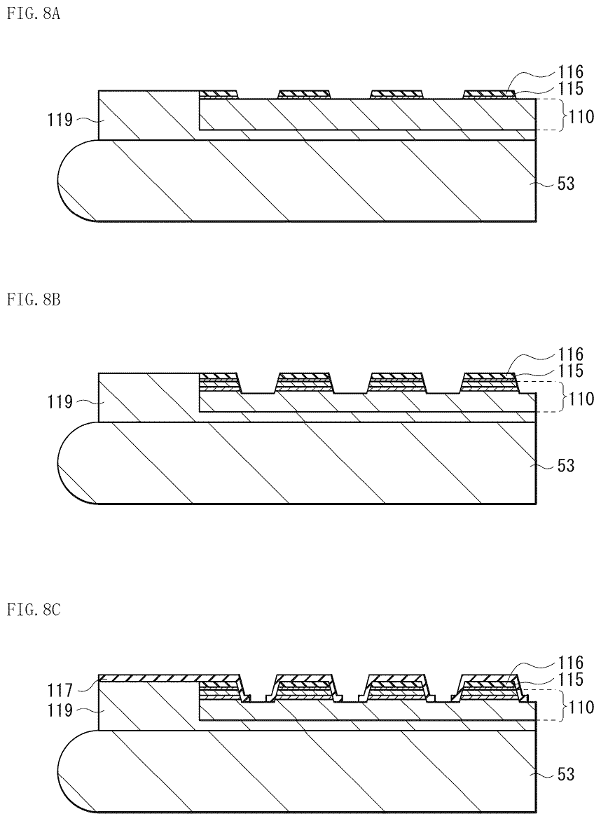

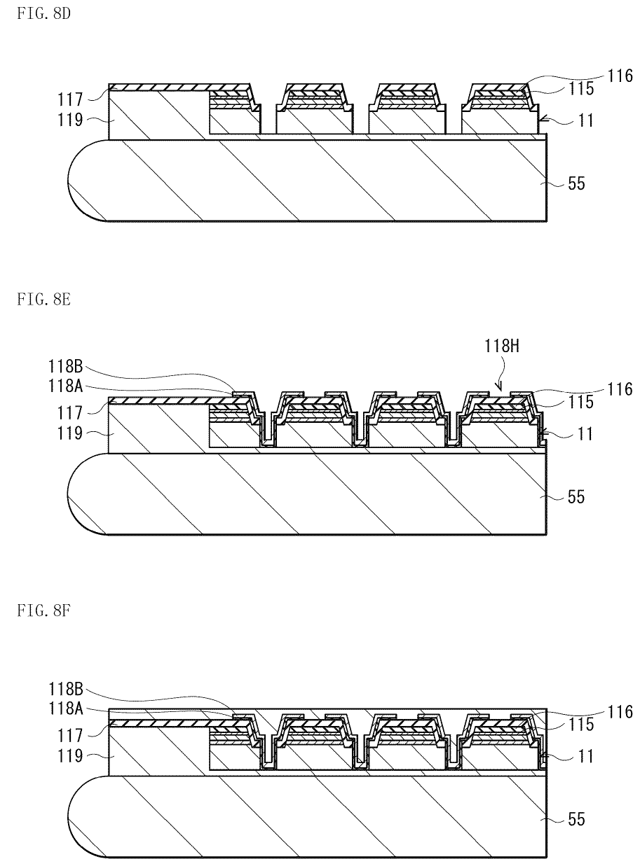

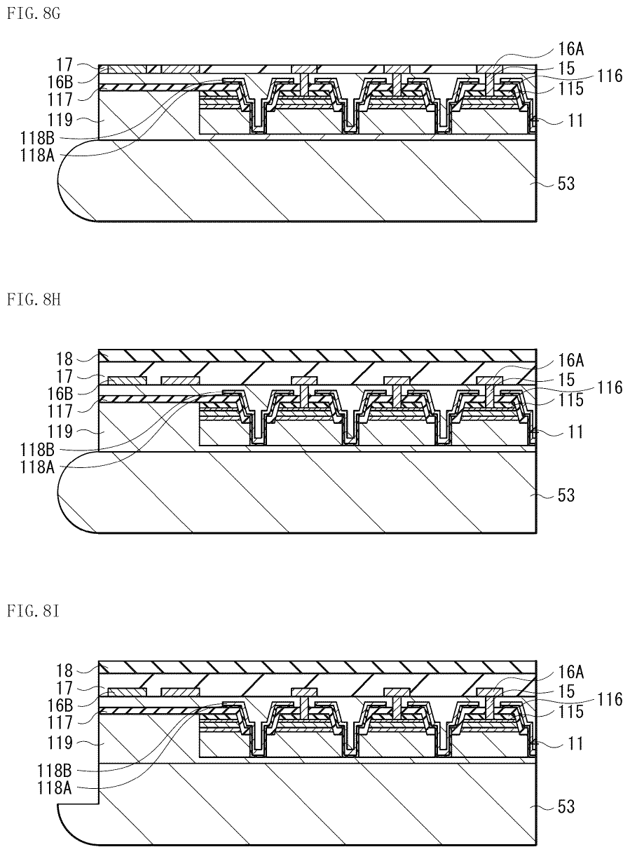

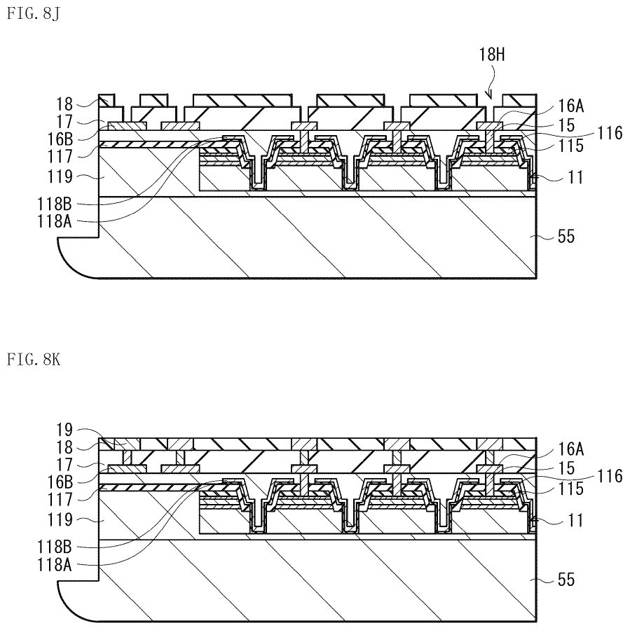

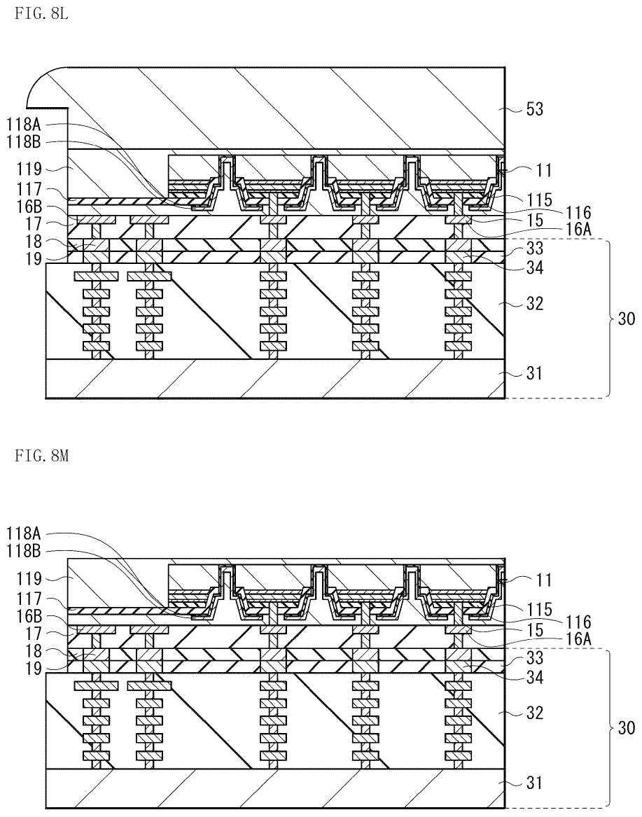

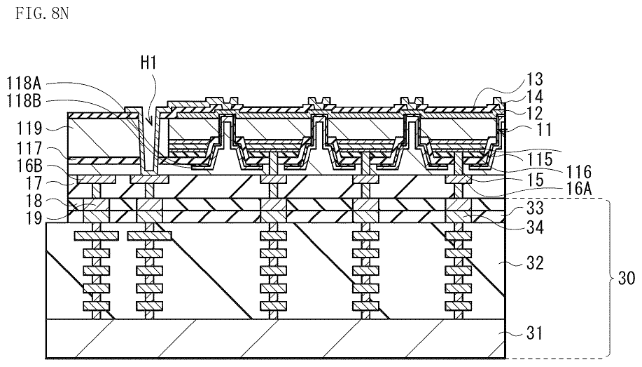

For example, it is possible to manufacture the light emitting device 1 according to the present embodiment as described below. FIG. 7A to FIG. 7I and FIG. 8A to FIG. 8N illustrate an example of manufacturing processes of the light emitting device 1.

First, as illustrated in FIG. 7A, a sapphire substrate 114 is used as a growth substrate, and the compound semiconductor layer 110 is formed through epitaxial crystal growth using molecular-beam epitaxy (MBE), metalorganic chemical vapor deposition (MOCVD), or the like, for example. Next, the electrode layer 115 and the insulating layer 116 are formed on the compound semiconductor layer 110 through chemical vapor deposition (CVD), for example. Next, a surface of the insulating layer 116 is planarized trough chemical mechanical polishing (CMP), for example.

Next, as illustrated in FIG. 7B, patterning is performed through etching the insulating layer 116, the electrode layer 115, and the compound semiconductor layer 110 by using a photolithography technology, for example. Next, as illustrated in FIG. 7C, the sapphire substrate 114 is transferred in such a manner that the insulating layer 116 faces a support substrate 51, and then the sapphire substrate 114 is broken and singulated. Next, as illustrated in FIG. 7D, the singulated sapphire substrates 114 are bonded to a support substrate 52 in such a manner that he insulating layers 116 face the support substrate 52.

Next, as illustrated in FIG. 7E, the sapphire substrates 114 are removed through, for example, grinding/polishing, and surfaces of the compound semiconductor layers 110 are planarized. Next, as illustrated in FIG. 7F, the embedding layer 119 is formed on the support substrate 52 through the CVD for example, and is planarized. Subsequently, as illustrated in FIG. 7G, edges of the embedding layer 119 and the support substrate 52 are trimmed. Next, as illustrated in FIG. 7H, the embedding layer 119 is joined to a support substrate 53 through plasma bonding for example. Subsequently, as illustrated in FIG. 7I, the support substrate 52 is peeled off. Next, a portion in a frame X in FIG. 7I will be enlarged and described.

First, as illustrated in FIG. 8A, patterning is performed through etching the insulating layer 116 and the electrode layer 115 provided on the compound semiconductor layer 110 by using the photolithography technology, for example. Next, as illustrated in FIG. 8B, a portion of the compound semiconductor layer 110 is etched through the photolithography technology for example, to form the mesa structure including the first conductivity-type layer 111, the active layer 112, and a portion of the second conductivity-type layer 113.

Next, an AIO film is formed over the upper surface of the insulating layer 116 and the side surfaces of the insulating layer 116, the electrode layer 115, and the mesa structure including the first conductivity-type layer 11, the active layer 112, and the second conductivity-type layer 113, and a bottom surface through, for example, atomic layer deposition (ALD), and then a SiN film is further formed through the CVD, for example. Subsequently, the SiN film is etched through, for example, the photolithography technology to form the protection layer 117 as a sidewall on the upper surface and the side surface of the mesa structure as illustrated in FIG. 8C.

Next, for example, as illustrated in FIG. 8D, the plurality of light emitting elements 11 is formed by separating the second conductivity-type layer 113 exposed from the protection layer 117 through the photolithography technology, for example. Next, an AlO film is formed through, for example, the ALD to cover the upper surface of the protection layer 117 and the side surfaces of the exposed light emitting elements 11. Next, as illustrated in FIG. 8E, the insulating film 118A and the reflection film 118B are sequentially formed through, for example, the CVD, and then the opening 118H is made in the upper surface of the mesa structure.

Next, as illustrated in FIG. 8F, the embedding layer 119 for planarization is formed again through, for example, the CVD. Subsequently, as illustrated in FIG. 8G, the plugs 15 for the respective light emitting elements 11 and the insulating layer 17 embedded with the plurality of pad sections 16A and the pad electrodes 16B are formed. Next, as illustrated in FIG. 8H, the insulating layer 17 is thickened, and the insulating layer 18 is formed on the insulating layer 17. Subsequently, as illustrated in FIG. 8I, the trimming is performed on their edges.

Next, as illustrated in FIG. 8J, openings 18H are made above the respective pad sections 16A and the respective pad electrodes 16B. Subsequently, as illustrated in FIG. 8K, the plurality of pad sections 19 are formed by embedding, for example, Cu into the openings 18H. Subsequently, surfaces of the insulating layer 18 and the plurality of pad sections 19 are polished through, for example, CMP to planarize the joint surface to be joined to the driving circuit substrate 30.

Next, as illustrated in FIG. 8L, through hybrid bonding, the plurality of pad sections 19 is bonded to the plurality of pad sections 34 of the driving circuit substrate 30 that has been formed separately. Subsequently, as illustrated in FIG. 8M, the support substrate 53 is peeled off. Next, as illustrated in FIG. 8N, an ITO film is formed through the CVD for example, and then the ITO film is patterned through the photolithography technology for example, to form the electrode layer 12. Next, as illustrated in FIG. 8N, the insulating layer 13 is formed through the CVD for example. Subsequently, through the photolithography technology, openings are made between the adjacent light emitting elements 11 and the opening H1 that reaches the pad electrode 16B is made. Next, as illustrated in FIG. 8N, a stacked film of Ti/W is formed through the CVD for example, and then extraction electrodes 14 are formed by patterning the stacked film through the photolithography technology for example.

Next, the planarizing layer 21 and the partition wall layer 22 are sequentially formed through the CVD, for example. Subsequently, the openings 22H are made in the partition wall layer 22 for respective pixels through the photolithography technology, for example. Next, the reflection films 24 are formed on side surfaces of the openings 22H by forming Al films on an upper surface of the partition wall layer 22 and the side surfaces and bottom surfaces of the openings 22H through the CVD for example, and then removing the Al films formed on the upper surface of the partition wall layer 22 and the bottom surfaces of the openings 22H through etchback. Next, the wavelength conversion layers 23 (23R, 23G, and 23B) for respective colors are formed in the openings 22H through a coating method such as an inkjet method for example. Subsequently, the protection layer 41 is formed on the partition wall layer 22 and the wavelength conversion layers 23, and then the on-chip lens layer 42 is bonded. In such a way, the light emitting device 1 illustrated in FIG. 1 is obtained.

### 1-3. Actions and Effects

The light emitting device 1 according to the present embodiment includes the two or more (for example, four) light emitting elements 11 having the mesa structure for each of color pixels Pr, Pg, and Pb. This makes it possible to add redundancy to each pixel. A description thereof will be provided below.

To improve resolution of light emitting devices that use LEDs as light sources, it is necessary to reduce its pixel pitch and refine its mesa structure constituting pixels associated therewith. The word “mesa” means a light emitting section (or independent light emitting element) of the image display device. However, when the LED mesa structure is refined, this deteriorates luminous efficacy drastically due to periphery effects in a region of, for example, 1 μm or less, and internal quantum efficiency (IQE) varies a lot.

In general, in a case where the light emitting device includes LEDs for respective pixels, redundancy is not added to the pixels. Therefore, it becomes a faulty chip if even one pixel does not satisfy a demand luminance value.

To solve this issue, there is a method of providing a plurality of LED mesa structures for each pixel. As described above, it is possible to obtain the plurality of LED mesas by covering a crystal growth substrate with a mask layer having a plurality of openings and by selectively growing one or a plurality of semiconductor rods through the MOCVD. However, when using the MOCVD, it is difficult to control the height. In a case of forming fine LED mesas, mesas have different luminances due to variation in their heights, which may become a huge challenge. In addition, the mesas themselves grow in a direction perpendicular to the crystal growth substrate, and this results in a disadvantage in light collection.

On the contrary, according to the present embodiment, the plurality of light emitting elements 11 separated through etching of the compound semiconductor layer 110 is disposed for each pixel (for example, red pixels Pr, green pixels Pg, and blue pixels Pb). This makes it possible to add redundancy to each pixel and reduce variation in luminance among pixels.

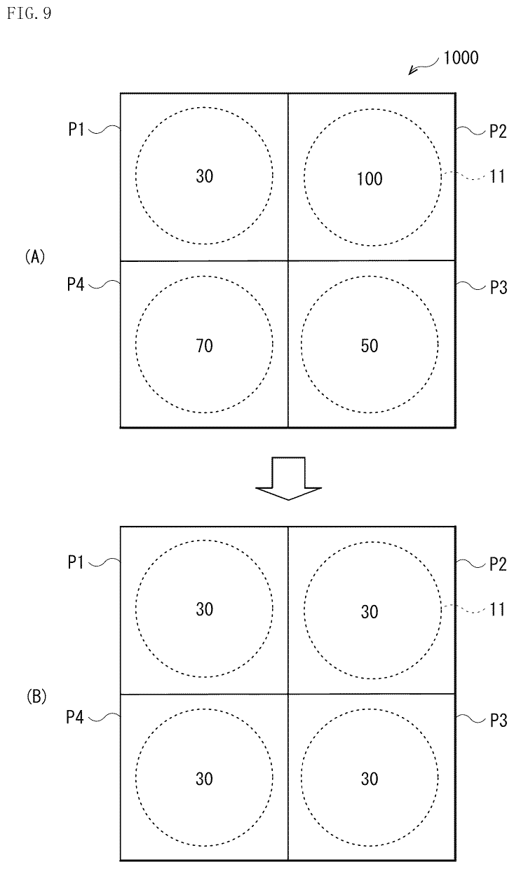

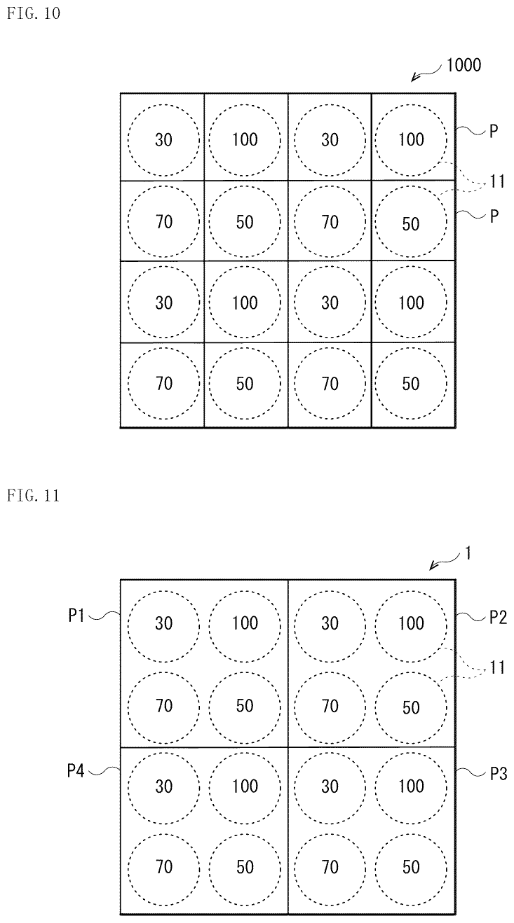

FIG. 9 illustrates (A) variations in luminance and (B) variations in post-correction luminance among pixels P1, P2, P3, and P4 of a general light emitting device 100 according to a comparative example. In a case where there are variations in luminance among respective pixels of the light emitting device 1000 in which a light emitting element 11 is disposed for each pixel, the variations in luminance among the pixels P are corrected by adjusting luminance levels of other pixels to a luminance level of a pixel having a lowest luminance, for example. That is, in a case where four pixels P1, P2, P3, and P4 disposed in two rows and two columns respectively have luminance levels of 30, 100, 50, and 70 as illustrated in (A) of FIG. 8, the luminance levels of the pixels P2, P3, and P4 are adjusted to the luminance level of the pixel P1 having the lowest luminance as illustrated in (B) of FIG. 8.

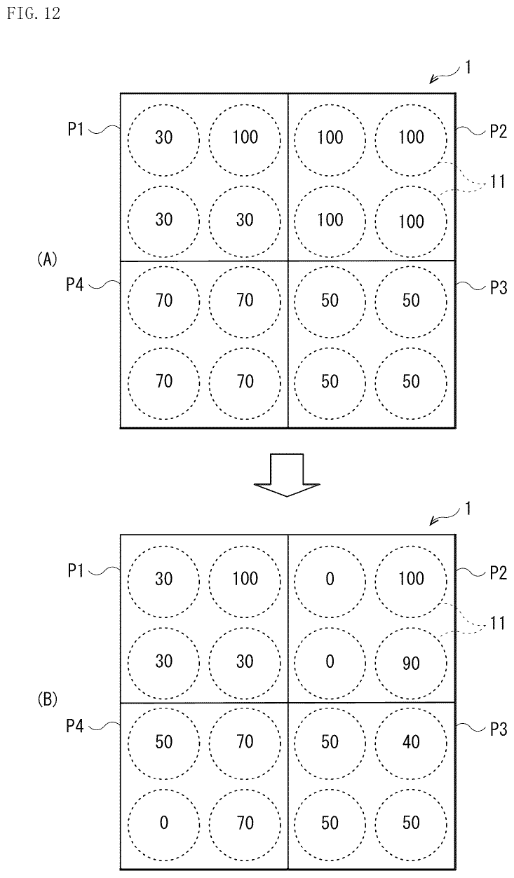

In a case where the light emitting element 11 are disposed for respective pixels in the light emitting device 1000 and there are variations in luminance among the light emitting elements 11 as illustrated in FIG. 10 and FIG. 11, the light emitting elements 11 disposed for the respective pixels P represent luminance of the pixels P as they are, as illustrated in FIG. 10. As described above, in a case where there are variations in luminance among the pixels P, luminance levels of other pixels are adjusted to a luminance level of a pixel having a lowest luminance, and the luminance level of the light emitting device 1000 becomes 30. On the contrary, even if there are variations in luminance among the light emitting elements 11 of the light emitting device 1 according to the present embodiment, an average luminance of four light emitting elements 11 in a pixel serves as a luminance of each of the pixels P1, P2, P3, and P4. Therefore, as illustrated in FIG. 11, the respective luminances of the four pixels P1, P2, P3, and P4 become 62.5, which is a higher luminance than the light emitting device 1000.

As described above, it becomes possible to achieve both refinement and improvement in luminance of the light emitting device 1 and the image display device 100 provided with the same according to the present embodiment.

In addition, according to the present embodiment, a single wavelength conversion layer 23 (for example, red wavelength conversion layer 23R, green wavelength conversion layer 23G, or blue wavelength conversion layer 23B) is disposed for the adjacent light emitting elements 11. This makes it possible to improve unevenness and variation in luminance among pixels due to refinement of mesa structures. Also, this makes it possible to disable generation of a faulty pixel serving as a bright dot, and it is possible to improve the production yield.

In addition, according to the present embodiment, the respective constant current driving circuits are coupled to the plurality of light emitting elements 11 disposed for each of the color pixels Pr, Pg, and Pb. This makes it possible to individually control emission of light from the respective light emitting elements 11.

FIG. 12 illustrates pre-correction luminances (A) and post-correction luminances (B) of the respective light emitting elements 11 in each of the pixels P of the light emitting device 1. As illustrated in (A) of FIG. 12, among the four pixels P1, P2, P3, and P4 disposed in two rows and two columns, an average luminance of four light emitting elements 11 in the pixel P1 becomes 47.5, which is a lowest average luminance. The other pixels P2, P3, and P4 select their light emitting elements 11 having higher luminances (higher IQE). In a case where the selected light emitting elements 11 satisfy the luminance of the pixel P1 having the lowest average luminance, their luminances are adjusted by selectively operating some of the light emitting elements disposed in the pixels P2, P3, and P4. Specifically, for example, the pixel P2 may selectively operate two of the four light emitting elements 11 whose luminance levels are 100, and may disable the other two light emitting elements 11 as illustrated in (B) of FIG. 12. In addition, for example, the pixel P4 may selectively operate three of the four light emitting elements 11 whose luminance levels are 70, and may disable the other light emitting element 11. The control elements 35 adjust amounts of electric current of the light emitting elements 11 to be operated in such a manner that the light emitting elements 11 to be operated have the luminance of the pixel P1. In such a way, highly efficient light emitting elements 11 are selectively operated, and this makes it possible to reduce load on a correction circuit. It is also possible to reduce electric power consumption.

Next, modifications and application examples of the present disclosure will be described. It is to be noted that structural elements corresponding to the above-described structural elements of the light emitting device 1 according to the above-described embodiment will be denoted with the same reference signs as the above-described embodiment, and repeated description will be omitted.

### 2. Modifications

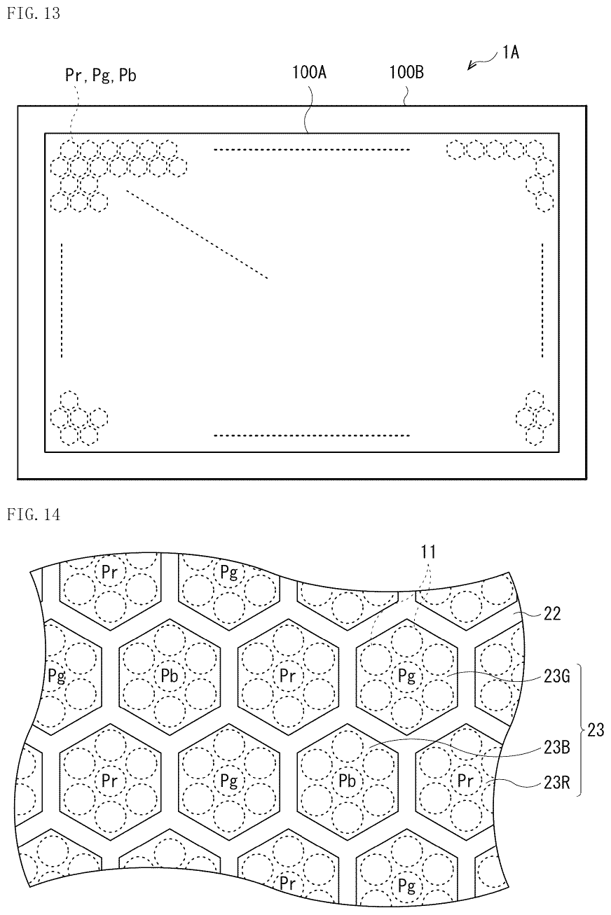

FIG. 13 schematically illustrates an example of a planar configuration of a whole light emitting device (light emitting device 1A) according to a modification of the present disclosure. FIG. 14 enlarges a portion of the planar configuration of the light emitting device 1A illustrated in FIG. 13.

In the above-described embodiment, each of the color pixels Pr, Pg, and Pb having substantially rectangular shapes includes the four light emitting elements 11 disposed in two rows and two columns. However, the present technology is not limited thereto.

The light emitting device 1A according to the present modification has a display region 100A and a frame region 100B, the display region 100A including a plurality of substantially regular hexagonal pixels (for example, red pixels Pr, green pixels Pg, and blue pixels Pb) that are disposed in a honeycomb pattern, the frame region 100B being disposed around the display region 100A. Each of the color pixels Pr, Pg, and Pb includes seven light emitting elements having mesa structures, for example. Even in such a configuration, it is possible to achieve effects that are similar to the effects according to the above-described embodiment.

### 3. Application Examples

### First Application Example

FIG. 15 is a perspective view illustrating an example of a schematic configuration of an image display device (image display device 100). The image display device 100 is a so-called LED display, and a light emitting device (for example, light emitting device 1) according to the present disclosure is used as display pixels. As illustrated in FIG. 15, for example, the image display device 100 includes a display panel 120 and a control circuit 140 that drives the display panel 120.

The display panel 120 is a display panel in which a mounting substrate 120A and a counter substrate 120B overlap each other. The counter substrate 120B has a surface serving as a picture display surface, and the surface has the display region 100A in its central part and the frame region 100B serving as a non-display region around the display region 100A.

FIG. 16 illustrates an example of wiring layout of a region corresponding to the display region 100A on a counter-substrate-120B-side surface of the mounting substrate 120A. As illustrated in FIG. 16, for example, a plurality of data wirings 121 is formed to extend in a predetermined direction and is disposed in parallel at a predetermined pitch in the region corresponding to the display region 100A on the surface of the mounting substrate 120A. The region corresponding to the display region 100A on the surface of the mounting substrate 120A further includes a plurality of scan wirings 122 that extend in a direction intersecting (for example, orthogonal to) the data wirings 121, and the plurality of scan wirings 125 is disposed in parallel at a predetermined pitch, for example. The data wirings 121 and the scan wirings 122 include, for example, conductive material such as Cu.

For example, the scan wiring 122 is formed on an uppermost layer, and is formed on an insulating layer (not illustrated) formed on a surface of a base material, for example. It is to be noted that the base material of the mounting substrate 120A includes, for example, a silicon substrate, a resin substrate, or the like. The insulating layer on the base material includes, for example, SiN, SiO, aluminum oxide (AIO), or resin material. On the other hand, the data wiring 121 is formed in a layer (for example, layer below the uppermost layer) different from the uppermost layer including the scan wiring 122. The data wiring 121 is formed in, for example, the insulating layer on the base material.

Intersections of the data wiring 121 and the scan wiring 122 and their surroundings serve as a display pixel 123. A plurality of the display pixels 123 is disposed in a matrix in the display region 100A. For example, the color pixels Pr, Pg, and Pb of the light emitting device 1 are implemented as the respective display pixels 123.

For example, the light emitting device 1 is provided with a pair of terminal electrodes for the respective color pixel Pr, Pg, and Pb, or is provided with a common terminal electrode and terminal electrodes for the respective color pixel Pr, Pg, and Pb. One of the terminal electrodes is electrically coupled to the data wiring 121, and another of the terminal electrodes is electrically coupled to the scan wiring 125. For example, the one of the terminal electrodes is electrically coupled to a pad electrode 121B at an end of a branch 121A of the data wiring 121. In addition, for example, the other of the terminal electrodes is electrically coupled to a pad electrode 122B at an end of a branch 122A of the scan wiring 122.

For example, the pad electrodes 121B and 122B are formed on the uppermost layer and is provided at parts where the respective light emitting devices 1 are mounted as illustrated in FIG. 16. Here, the pad electrodes 121B and 122B include electrically conductive material such as Au (gold), for example.

The mounting substrate 120A is further provided with, for example, a plurality of support columns (not illustrated) for regulating an interval between the mounting substrate 120A and the counter substrate 120B. The support columns may be provided in a region opposed to the display region 100A or may be provided in a region opposed to the frame section 100B.

The counter substrate 120B includes, for example, a glass substrate, a resin substrate, or the like. The counter substrate 120B may have a flat surface on the light-emitting-device 1 side, but preferably has a rough surface. The rough surface may be provided over a whole region opposed to the display region 100A, or may be provided in a region opposed to the display pixels 123 only. The rough surface has fine irregularities into which light emitted from the color pixels Pr, Pg, and Pb enters. It is possible to make the irregularities on the rough surface through sand blasting, dry etching, or the like, for example.

The control circuit 140 drives the respective display pixels 123 (respective light emitting devices 1) on the basis of picture signals. The control circuit 140 includes, for example, a data driver that drives the data wirings 121 coupled to the display pixels 123 and a scan driver that drives the scan wirings 122 coupled to the display pixels 123. For example, as illustrated in FIG. 15, the control circuit 140 may be provided separately from the display panel 120 and may be coupled to the mounting substrate 120A via the wirings, or may be mounted on the mounting substrate 120A.

### Second Application Example

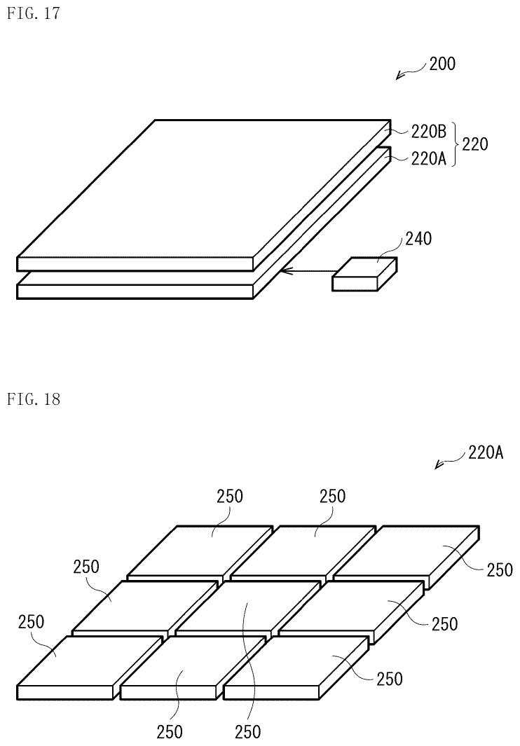

FIG. 17 is a perspective view illustrating another configuration example of the image display device (image display device 200) that uses the light emitting device (for example, light emitting device 1) according to the present disclosure. The image display device 200 is a so-called tiling display that uses the plurality of light emitting devices including LEDs as light sources. For example, as illustrated in FIG. 17, the image display device 200 includes a display panel 220 and a control circuit 240 that drives the display panel 220.

The display panel 220 is a display panel in which a mounting substrate 220A and a counter substrate 220B overlap each other. The counter substrate 220B has a surface serving as a picture display surface, and the surface has a display section in its central part and a frame region serving as a non-display region around the display region (both regions are not illustrated). For example, the counter substrate 220B is disposed at a position opposed to the mounting substrate 220A with a predetermined gap therebetween. It is to be noted that the counter substrate 220B may be in contact with an upper surface of the mounting substrate 220A.

FIG. 18 schematically illustrates an example of a configuration of the mounting substrate 220A. For example, as illustrated in FIG. 18, the mounting substrate 220A includes a plurality of unit substrates 250 laid like tiles. Although FIG. 18 illustrates the example in which the mounting substrate 220A includes the nine unit substrates 250, the number of unit substrates 250 may be 10 or more or 8 or less.

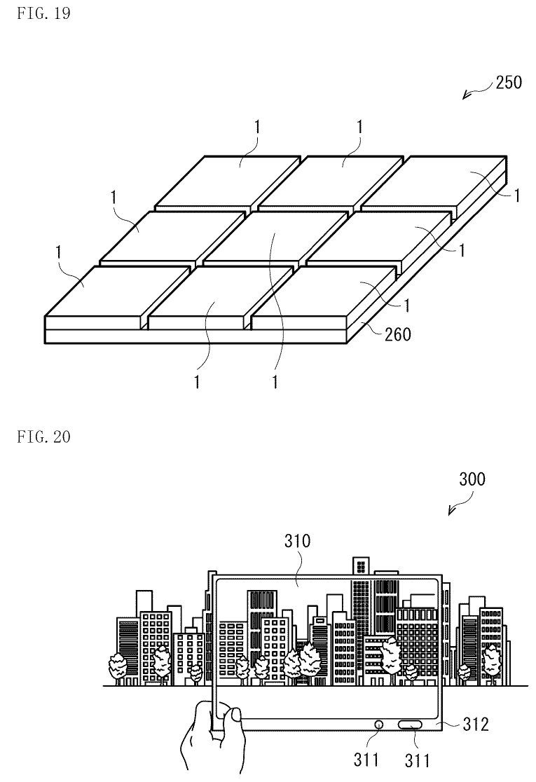

FIG. 19 illustrates an example of a configuration of the unit substrate 250. For example, the unit substrate 250 includes a plurality of light emitting devices 1 laid like tiles and a support substrate 260 that supports the light emitting devices 1. Each unit substrate 250 further includes a control substrate (not illustrated). The support substrate 260 is implemented by a metal frame (metal plate), a wiring substrate, or the like, for example. In a case where the support substrate 260 is implemented by the wiring substrate, the support substrate 260 may also serve as the control substrate. In this case, at least one of the support substrate 260 or the control substrate is electrically coupled to the respective light emitting devices 1.

### Third Application Example

FIG. 20 illustrates an appearance of a transparent display 300. The transparent display 300 includes, for example, a display section 310, an operation section 311, and a housing 312. The display section 310 uses the light emitting device (for example, light emitting device 1) according to the present disclosure. The transparent display 300 makes it possible to display images, text information, and the like while letting a background of the display section 310 to pass through.

The transparent display 300 includes a mounting substrate that has light transparency. The light emitting device 1 is provided with electrodes, each of which is formed by using electrically conductive material having light transparency like the mounting substrate. Alternatively, the electrodes have a structure that is difficult to be visually recognized by supplementing their wiring width or by thinning the thickness of the wiring. Further, it is possible to display black on the transparent display 300 by superimposing liquid crystal layers provided with a driving circuit, for example. This makes it possible to switch between a transparent mode and a black display mode by controlling light distribution directions of liquid crystals.

The present technology has been described above with reference to the embodiments, modifications, and application examples. However, the present technology is not limited thereto, and various kinds of modifications thereof can be made. For example, the example in which light emitted from the light emitting element 11 is blue light or ultraviolet light has been described in the above-described embodiment or the like. However, the present technology is not limited thereto. For example, the light emitting device 1 may use light emitting elements that emit two or more types of light such as a set of blue light and green light or a set of ultraviolet light and green light.

Further, in the above-described embodiments and the like, the respective members included in the light emitting device 1 and the like have been specifically described, but it is not necessary to include all the members, and other members may be further provided.

It is to be noted that the effects described herein are only for illustrative purposes and there may be other effects.

The present technology may be configured as follows. According to the present technology having the following configurations, two or more light emitting elements having mesa structures are disposed for each pixel. This makes it possible to add redundancy to each pixel, and to achieve both refinement and improvement in luminance.
(1)
   A light emitting device including:
   a driving circuit substrate; and
   an element substrate that has a first surface and a second surface, the first surface serving as a light exit surface, the second surface being on a side opposite to the first surface and being opposed to the driving circuit substrate, that includes a pixel array section including a plurality of pixels disposed in an array form, and that includes two or more light emitting elements having mesa structures for each of the pixels.
(2)
   The light emitting device according to (1), in which the element substrate further includes a wavelength conversion layer that is provided for each of the pixels and that converts wavelength of light emitted from the two or more light emitting elements disposed for each of the pixels.
(3)
   The light emitting device according to (1) or (2), further including
   a micro lens layer on a side of the first surface of the element substrate, the micro lens layer including a micro lens for each of the pixels, the micro lens outputting light emitted from the two or more light emitting elements disposed for each of the pixels into a predetermined direction.
(4)
   The light emitting device according to any one of (1) to (3), in which
   the driving circuit substrate includes a plurality of constant current driving circuits that flow a fixed electric current, and
   the plurality of constant current driving circuits includes respective control elements that control electric currents flowing in the plurality of light emitting elements, and is coupled to the respective light emitting elements individually.
(5)
   The light emitting device according to any one of (1) to (4), in which
   the driving circuit substrate includes a plurality of constant current driving circuits that flow a fixed electric current, and
   the plurality of constant current driving circuits includes respective control elements that control electric currents flowing in the plurality of light emitting elements, each of the constant current driving circuits being coupled to the two or more light emitting elements disposed for each of the pixels.
(6)
   The light emitting device according to (5), in which the two or more light emitting elements disposed for each of the pixels are coupled to each other, and are electrically coupled to the constant current driving circuit.
(7)
   The light emitting device according to any one of (1) to (6), in which the driving circuit substrate has a third surface opposed to the second surface of the element substrate and a fourth surface disposed on a side opposite to the third surface, and includes a plurality of constant current driving circuits that flow a fixed electric current.
(8)
   The light emitting device according to (7), in which
   the second surface of the element substrate is further provided with a plurality of first pad sections that is electrically coupled to the plurality of light emitting elements via plugs,
   the third surface of the driving circuit substrate is further provided with a plurality of second pad sections that is electrically coupled to the respective constant current driving circuits, and
   the plurality of light emitting elements and the plurality of constant current driving circuits are electrically coupled via the plurality of first pad sections and the plurality of second pad sections.
(9)
   An image display device including
   a light emitting device including
      a driving circuit substrate, and
      an element substrate that has a first surface and a second surface, the first surface serving as a light exit surface, the second surface being on a side opposite to the first surface and being opposed to the driving circuit substrate, that includes a pixel array section including a plurality of pixels disposed in an array form, and that includes two or more light emitting elements having mesa structures for each of the pixels.

The present application claims the benefit of Japanese Priority Patent Application JP2023-024685 filed with the Japan Patent Office on Feb. 20, 2023, the entire contents of which are incorporated herein by reference.

It should be understood by those skilled in the art that various modifications, combinations, sub-combinations and alternations may occur depending on design requirements and other factors insofar as they are within the scope of the appended claims or the equivalents thereof.

What is claimed is:

1. A light emitting device, comprising:
a driving circuit substrate; and
an element substrate that has a first surface and a second surface, the first surface serving as a light exit surface, the second surface being on a side opposite to the first surface and being opposed to the driving circuit substrate, that includes a pixel array section including a plurality of pixels disposed in an array form, and that includes two or more light emitting elements having mesa structures for each of the pixels.

2. The light emitting device according to claim 1, wherein the element substrate further includes a wavelength conversion layer that is provided for each of the pixels and that converts wavelength of light emitted from the two or more light emitting elements disposed for each of the pixels.

3. The light emitting device according to claim 1, further comprising
a micro lens layer on a side of the first surface of the element substrate, the micro lens layer including a micro lens for each of the pixels, the micro lens outputting light emitted from the two or more light emitting elements disposed for each of the pixels into a predetermined direction.

4. The light emitting device according to claim 1, wherein
the driving circuit substrate includes a plurality of constant current driving circuits that flow a fixed electric current, and
the plurality of constant current driving circuits includes respective control elements that control electric currents flowing in the plurality of light emitting elements, and is coupled to the respective light emitting elements individually.

5. The light emitting device according to claim 1, wherein
the driving circuit substrate includes a plurality of constant current driving circuits that flow a fixed electric current, and
the plurality of constant current driving circuits includes respective control elements that control electric currents flowing in the plurality of light emitting elements, each of the constant current driving circuits being coupled to the two or more light emitting elements disposed for each of the pixels.

6. The light emitting device according to claim 5, wherein the two or more light emitting elements disposed for each of the pixels are coupled to each other, and are electrically coupled to the constant current driving circuit.

7. The light emitting device according to claim 1, wherein the driving circuit substrate has a third surface opposed to the second surface of the element substrate and a fourth surface disposed on a side opposite to the third surface, and includes a plurality of constant current driving circuits that flow a fixed electric current.

8. The light emitting device according to claim 7, wherein
the second surface of the element substrate is further provided with a plurality of first pad sections that is electrically coupled to the plurality of light emitting elements via plugs,
the third surface of the driving circuit substrate is further provided with a plurality of second pad sections that is electrically coupled to the respective constant current driving circuits, and
the plurality of light emitting elements and the plurality of constant current driving circuits are electrically coupled via the plurality of first pad sections and the plurality of second pad sections.

9. An image display device, comprising
a light emitting device including
a driving circuit substrate, and
an element substrate that has a first surface and a second surface, the first surface serving as a light exit surface, the second surface being on a side opposite to the first surface and being opposed to the driving circuit substrate, that includes a pixel array section including a plurality of pixels disposed in an array form, and that includes two or more light emitting elements having mesa structures for each of the pixels.
